(19) United States
(12) Patent Application Publication
(10) Pub. No.: US 2016/0190146 A1
(43) Pub. Date: Jun. 30, 2016

(54) INTEGRATED CIRCUITS AND METHODS FOR FABRICATING MEMORY CELLS AND INTEGRATED CIRCUITS

(71) Applicant: GLOBAL FOUNDRIES Singapore Pte. Ltd.

(72) Inventors: Zufa Zhang, Singapore (SG); Khee Yong Lim, Singapore (SG); Xinshu Cai, Singapore (SG)

(21) Appl. No.: 14/584,934

(22) Filed: Dec. 29, 2014

(51) Int. Cl. H01L 27/115; H01L 29/423; H01L 23/528; H01L 29/49; H01L 21/28; H01L 29/66; H01L 21/3213; H01L 29/788; H01L 29/06

(52) U.S. Cl. CPC H01L 27/11521; H01L 29/7883; H01L 29/42328; H01L 23/528; H01L 29/0642; H01L 21/28273; H01L 29/66825; H01L 21/32133; H01L 29/4925

(57) ABSTRACT

Integrated circuits and methods fabricating memory cells and integrated circuits are provided. In one embodiment, a method for fabricating a memory cell includes doping a semiconductor substrate to define a conductive region. The method includes forming a stacked structure over the semiconductor substrate. The stacked structure lies over the conductive region and includes a control gate overlying a floating gate. A source line region is formed adjacent a first side of the stacked structure. The method includes forming a contact over the semiconductor substrate and adjacent a second side of the stacked structure to define an electrical current path from the source line region through the conductive region under the stacked structure to the contact.

### TECHNICAL FIELD

The present disclosure generally relates to integrated circuits and methods for fabricating integrated circuits, and more particularly relates to integrated circuits having source line regions with improved electrical current paths, methods for fabricating memory cells having such source line regions, and methods for fabricating integrated circuits having such source line regions.

### BACKGROUND

Wide varieties of semiconductor memory devices have been developed. These semiconductor memory devices are continuously employed in new and expanded uses, which require an integrated circuit of increased capabilities and decreased cost. Accordingly, there exists a continuing demand for inexpensive semiconductor devices having increased memory and reduced chip size. Many semiconductor devices include multiple types of circuits such as memory and logic circuits. Flash memory cells are typically formed, along with other circuits (non-memory circuits) such as core circuits, as embedded flash memory. Flash memory cells may be included in system on a chip (SOC) devices.

Flash memory has become increasingly popular in recent years. A typical flash memory includes a memory array having a large number of memory cells arranged in blocks. Each of the flash memory cells is fabricated as a field-effect transistor having a control gate and a floating gate. The floating gate is capable of holding charges and is separated from source and drain regions contained in a substrate by a layer of thin oxide. The memory cells may be capable of several operations including program, read, write, and erase. For example, memory cells may be electrically charged by injecting electrons from the drain region through the oxide layer onto the floating gate. The charges may be removed from the floating gate, in one known approach, by tunneling the electrons to the source through the oxide layer during an erase operation. The data in a memory cell is thus determined by the presence or absence of a charge on the floating gate.

To provide for electrical charging of memory devices, integrated circuit fabrication schemes typically form and connect conductive vias to contacts formed on the memory device components, including word line and source line regions, and control gates. Different arrangements may be formed for different purposes. For example, a memory cell may have conductive vias in electrical connection with two control gates and with a common source line region therebetween. Further, a memory cell may have conductive vias in electrical connection with two word lines and with a common source line region. Another memory cell may have a single conductive via in electrical connection with the source line region.

The formation of multiple conductive vias in close proximity leads to possible shorting, particularly between word line and source line conductive vias. Further, connection to source line regions with a conductive via typically requires removal of erase gate polysilicon to expose the source line region. Such removal typically removes portions of the control gate polysilicon and may lead to erase gate to control gate bridging, as well as induce low source line junction reverse-breakdown voltage (BV). Also, formation of a silicide contact on the source line region may cause control gate to source line shorting.

Accordingly, it is desirable to provide integrated circuits and methods for fabricating memory cells and integrated circuits having improved electrical conductive paths to source lines. Furthermore, other desirable features and characteristics will become apparent from the subsequent detailed description and the appended claims, taken in conjunction with the accompanying drawings and the foregoing technical field and background.

### BRIEF SUMMARY

Integrated circuits and methods fabricating memory cells and integrated circuits are provided. In an exemplary embodiment, a method for fabricating a memory cell includes doping a semiconductor substrate to define a conductive region. The method includes forming a stacked structure over the semiconductor substrate. The stacked structure lies over the conductive region and includes a control gate overlying a floating gate. A source line region is formed adjacent a first side of the stacked structure. The method includes forming a contact over the semiconductor substrate and adjacent a second side of the stacked structure to define an electrical current path from the source line region through the conductive region under the stacked structure to the contact.

In another embodiment, a method for fabricating an integrated circuit includes forming a flash memory cell including a floating gate overlying a semiconductor substrate and a source line region adjacent a first side of the floating gate. The method also includes forming a contact over the semiconductor substrate adjacent a second side of the floating gate and defining an electrical current path from the contact, under the floating gate, and to the source line region.

In accordance with another embodiment, an integrated circuit is provided. The integrated circuit includes a semiconductor substrate and a source line region in or overlying the semiconductor substrate. The integrated circuit further includes a contact in or overlying the semiconductor substrate and defining an electrical current path between the contact and the source line region. Also, the integrated circuit includes a gate overlying the semiconductor substrate and located between the source line region and the contact, wherein the electrical current path passes under the gate.

### BRIEF DESCRIPTION OF THE DRAWINGS

Embodiments of integrated circuits, methods for fabricating integrated circuits, and methods for fabricating memory cells will hereinafter be described in conjunction with the following drawing figures, wherein like numerals denote like elements, and wherein:

FIGS. 1-16 illustrate, in overhead views and cross sectional views, a portion of an integrated circuit and method steps for fabricating the integrated circuit in accordance with various embodiments herein.

### DETAILED DESCRIPTION

The following detailed description is merely exemplary in nature and is not intended to limit the integrated circuits, the methods for fabricating integrated circuits, or the methods for fabricating memory cells as claimed herein. Furthermore, there is no intention to be bound by any expressed or implied theory presented in the preceding technical field, background or brief summary, or in the following detailed description.

In accordance with the various embodiments herein, integrated circuits, methods for fabricating integrated circuits, and methods for fabricating memory cells are provided. Generally, the following embodiments relate to the formation of split-gate flash memory cell. In conventional processing, contacts and conductive vias are located directly over source line regions to provide for electrical connection thereto. As described herein, exemplary fabrication methods provide the source line region of the memory cell with a buried, horizontal electrical conductive path to a contact horizontally distanced from the source line region. A vertical conductive via may be in electrical connection with the contact. In exemplary embodiments, the electrical conductive path passes under a memory cell gate, such as a floating gate or a floating gate/control gate stack. Further, the exemplary electrical conductive path passes under a word line region adjacent the floating gate/control gate stack.

As a result of the structure and methods described herein, shorting at the conductive via connected to the source line region may be reduced, bridging at the erase gate positioned over the source line region may be reduced, and shorting between the source line region and the control gate may be reduced. Further, the integrated circuit fabrication process margin may be enlarged by reducing the bridging possibility. The arrangement described herein may also provide for a reduction in electrical connection area, i.e., strap width. Further the methods described herein may be provided without any extra masking steps over conventional fabrication methods.

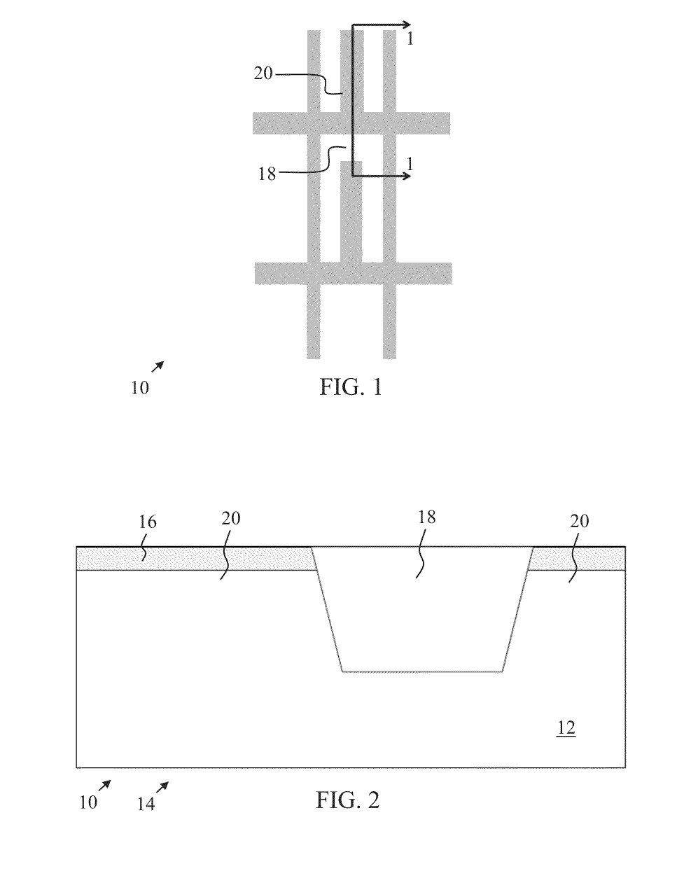

FIGS. 1-16 illustrate sequentially a method for fabricating an integrated circuit having a memory cell in accordance with various embodiments herein. Each odd-numbered figure is an overhead view and each even-numbered figure is a cross-sectional view taken long line 1-1 of the preceding overhead view. The drawings are semi-diagrammatic and not to scale and, particularly, some of the dimensions are for the clarity of presentation and are shown exaggerated in the drawings. Similarly, although the views in the drawings for ease of description generally show similar orientations, this depiction in the drawings is arbitrary. Generally, the integrated circuit can be operated in any orientation. Also, terms such as “overlying”, “over”, “under”, “vertical” and “horizontal” are used in the context of the drawing orientations and are not meant to be limited to the particular illustrated orientation. Various steps in the design and composition of integrated circuits are well known and so, in the interest of brevity, many conventional steps will only be mentioned briefly herein or will be omitted entirely without providing the well-known process details. Further, it is noted that integrated circuits include a varying number of components and that single components shown in the illustrations may be representative of multiple components.

Turning now to FIGS. 1 and 2, in an exemplary embodiment, the process of fabricating an integrated circuit 10 includes providing a semiconductor substrate 12. The semiconductor substrate 12 for example is a silicon material as typically used in the semiconductor industry, e.g., relatively pure silicon as well as silicon admixed with other elements such as germanium, carbon, and the like. Alternatively, the semiconductor material can be germanium, gallium arsenide, or the like. The semiconductor material may be provided as a bulk semiconductor substrate, or it could be provided on a silicon-on-insulator (SOI) substrate, which includes a support substrate, an insulator layer on the support substrate, and a layer of silicon material on the insulator layer. Further, the semiconductor substrate 12 may optionally include an epitaxial layer (epi layer). Also, the semiconductor substrate 12 may be doped as desired.

FIGS. 1-2 illustrate a memory area 14 of the semiconductor substrate 12. A silicon nitride layer 16, known as a pad nitride, and isolation regions 18 are formed over the semiconductor substrate 12 according to conventional processing. Exemplary isolation regions 18 are shallow trench isolation (STI) zones. Outside of isolation regions 18, active regions 20 are defined in the remaining semiconductor substrate 12. STI zones 18 may be formed by initially creating a shallow trench in the silicon nitride layer 16 and semiconductor substrate 12. For example a conventional photolithographic and anisotropic etch process may be used such as with a dry etch process, e.g., reactive ion etching (RIE) procedure using, for example, Cl₂ as the etchant. After removal of the photoresist pattern used for shallow trench definition, e.g., by plasma oxygen ashing and wet cleans, an insulating layer such as a silicon oxide layer is deposited, for example by a low pressure chemical vapor deposition (LPCVD) procedure or by a plasma enhanced chemical vapor deposition (PECVD) procedure or other procedure. The shallow trenches are thus completely filled. Removal of the insulating material, silicon oxide in the example given, from regions other than inside the shallow trenches is accomplished using any suitable technique such as either a chemical mechanical polishing (CMP) procedure, or by a RIE procedure using a suitable etchant, resulting in insulator filled STI zones 18.

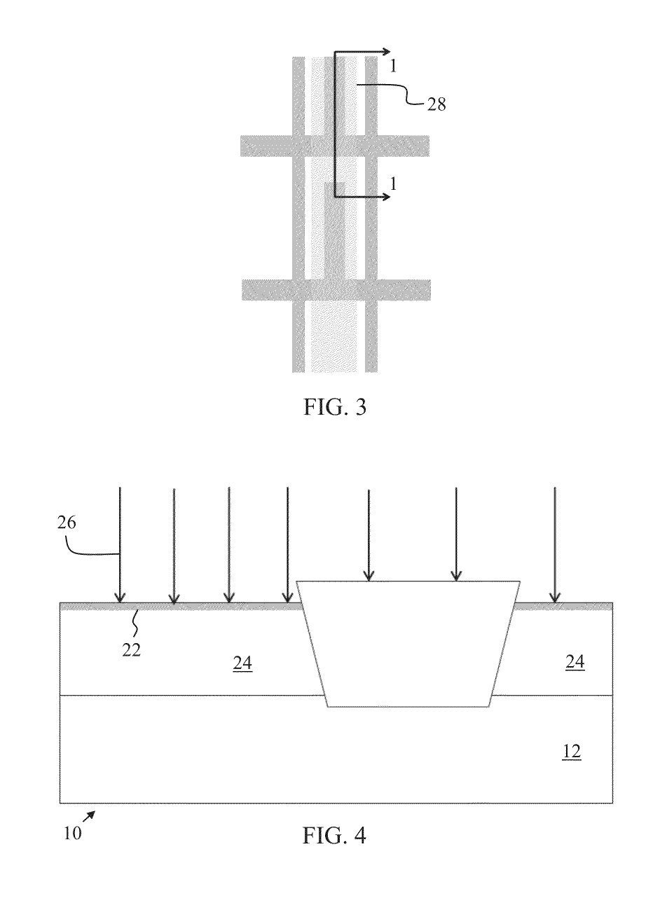

In FIGS. 3-4, the silicon nitride layer 16 is removed and a dielectric layer 22 may be formed on the semiconductor substrate 12. An exemplary dielectric layer 22 is silicon dioxide (“oxide”). In an exemplary embodiment, the dielectric layer 22 is formed by thermal oxidation or another well known technique such as chemical vapor deposition (CVD).

Further, a doping process is performed to form well regions 24 in the semiconductor substrate 12. For example, ions, indicated by arrows 26, may be implanted to form well regions 24. The overhead view of FIG. 4 illustrates a mask with mask opening 28 for performing the implantation process on selected areas of the semiconductor substrate 12.

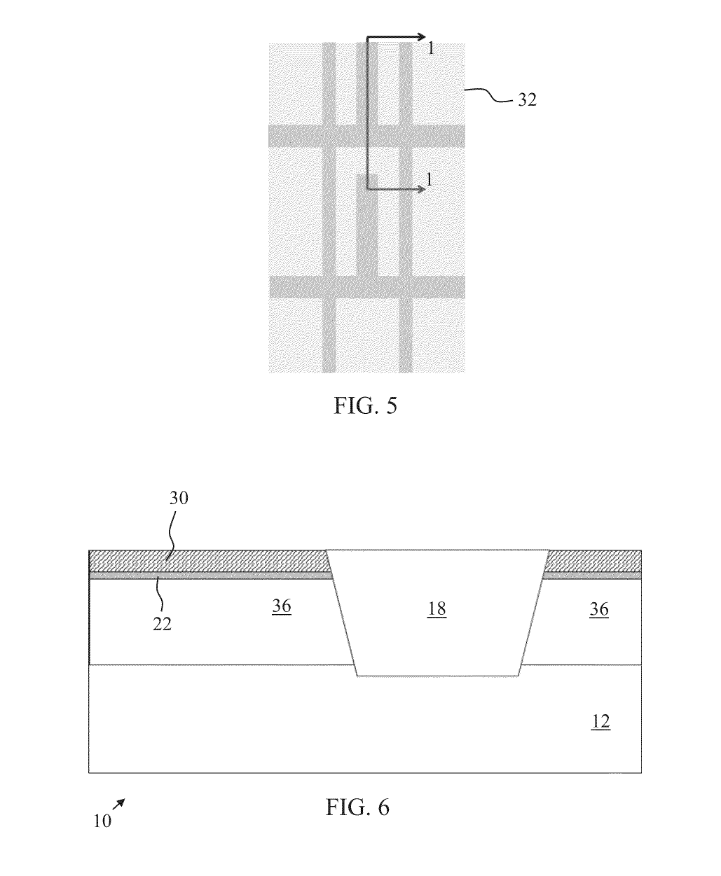

In FIGS. 5-6, a gate conductor material 30 is deposited over the dielectric layer 22 in the portion of the integrated circuit 10 exposed by mask opening 32. The gate conductor material 30 will be later processed to form floating gates. The gate conductor material 30 may be polycrystalline silicon (“polysilicon”). The deposition of the gate conductor material 30 may be performed by a well known process such as LPCVD. The gate conductor material 30 may be planarized, such as by a chemical mechanical planarization process to the height of STI zones 18. In FIG. 6, another implantation process may be performed for further doping of the semiconductor substrate 12 to form a memory cell well 36. For example, an N type well 36 may be formed.

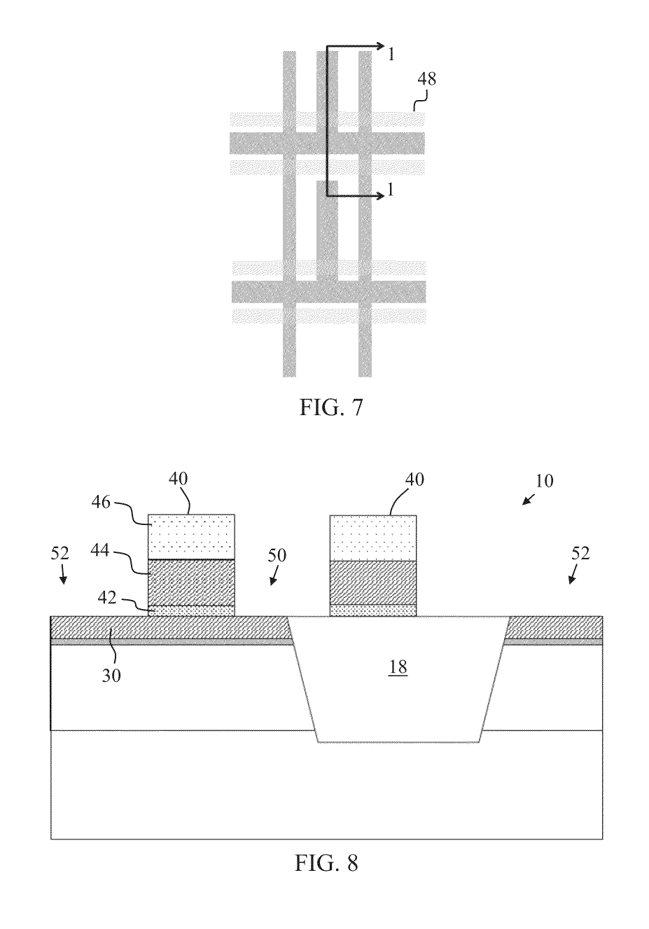

FIGS. 7-8 illustrates further deposition and patterning of layers to form control gate stacks 40. Specifically, an insulating layer 42, a gate conductor material 44 and a cap material 46 are sequentially formed over the gate conductor material 30 and isolation region 18 and patterned. An exemplary insulating layer 42 is an inter-polysilicon dielectric (“IPD”) layer. For example, the insulating layer 42 may be formed as a stack structure of an oxide layer, nitride layer, and oxide layer, i.e., an “ONO” stack. The insulating layer 42 may be formed by an appropriate oxidation or deposition process.

The gate conductor material 44 may be formed of polysilicon. The gate conductor material 44 may be deposited by a well known process such as LPCVD. The cap material 46 may be silicon nitride (“nitride”) or another suitable hard mask material. For example, the cap material 46 may be a nitride layer, oxide layer, nitride layer stack, i.e., a “NON” stack. In an exemplary embodiment, the cap material 46 is deposited over the gate conductor material 44 by CVD processes.

A mask 48 is formed over the integrated circuit 10 and then the cap material 46, gate conductor material 44, and insulating layer 42 are etched using the mask 48 to form the two gate stacks 40. The gate stacks 40 define an area 50 between the gate stacks 40 that will be used to form a source line region. Area 50 may be referred to as source line area 50 for purposes of clarity. The gate stacks 40 further define areas 52 where select gates will be formed and may be referred to as select gate areas 52.

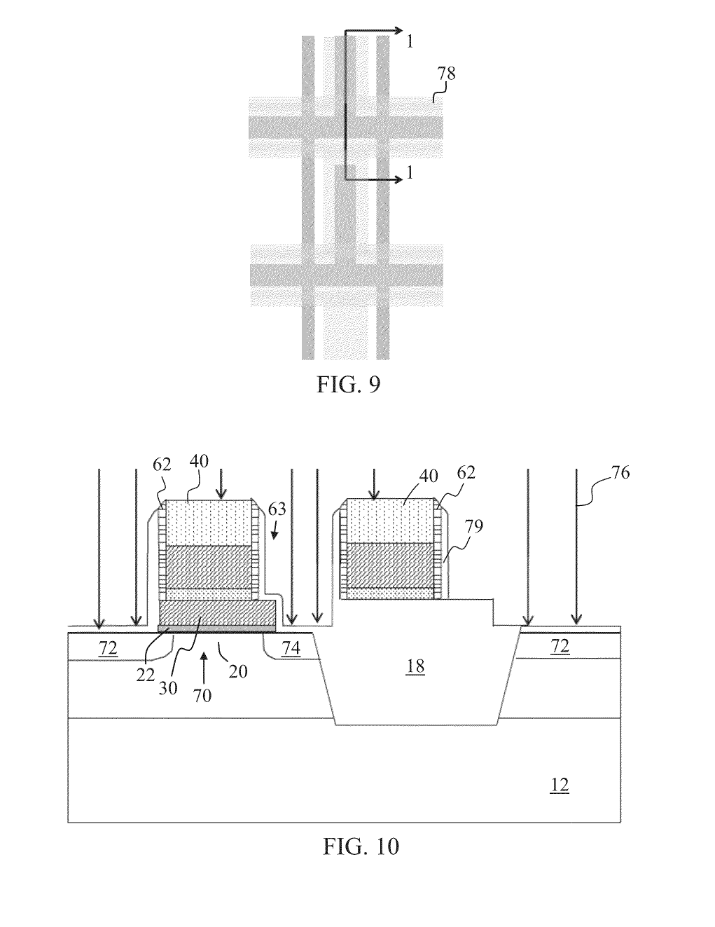

In FIGS. 9-10, first spacers 62 and a second spacer (not shown) are formed around the gate stacks 40. In an exemplary embodiment, first spacers 62 are oxide layers formed by any suitable method. Typically, a spacer-forming layer is deposited over the semiconductor substrate 12 and gate stacks 40 and then etched, such as by RIE to form first spacers 62 as shown. A second spacer-forming layer is then deposited over the semiconductor substrate 12 and gate stacks 40. The second spacer-forming layer may be formed by LPCVD or PECVD. Then an anisotropic etch is performed to remove the second spacer from areas other than at location 63. For example, the source line area 50 may be masked while the second spacer in other locations is etched. The mask is then removed.

As shown, a floating gate etch is performed using the remaining second spacer (not shown) at location 63 and the first spacers 62 as a mask. The gate conductor material 30 and dielectric layer 22 are etched using the first spacers 62 and second spacer as an etch mask. In an exemplary embodiment, the gate conductor material 30 and gate dielectric layer 22 are etched anisotropically by, for example, a RIE process. As a result, a floating gate structure 70 is formed under the control gate stack 40 overlying active region 20.

After formation of the floating gate structure 70, an ion implantation process or doping process may be performed to form shallow doped regions 72 and a source line junction or region 74 in the semiconductor substrate 12. In an exemplary embodiment, the shallow doped regions 72 and source line region 74 are N⁺ doped. In an exemplary embodiment, ions indicated by arrows 76 are implanted in the semiconductor substrate 12 to form the shallow doped regions 72 and source line region 74, while a mask with mask opening 78 is overlying the semiconductor substrate 12. After etching the gate conductor material, a wet etch process may be performed to remove the second spacer at location 63. The wet etch may remove portions of the isolation region 18. Then, a tunnel oxide layer 79 may be formed over the semiconductor substrate 12 and around the gate stacks 40. An exemplary tunnel oxide layer 79 has a thickness of from about 7 nm to about 15 nm.

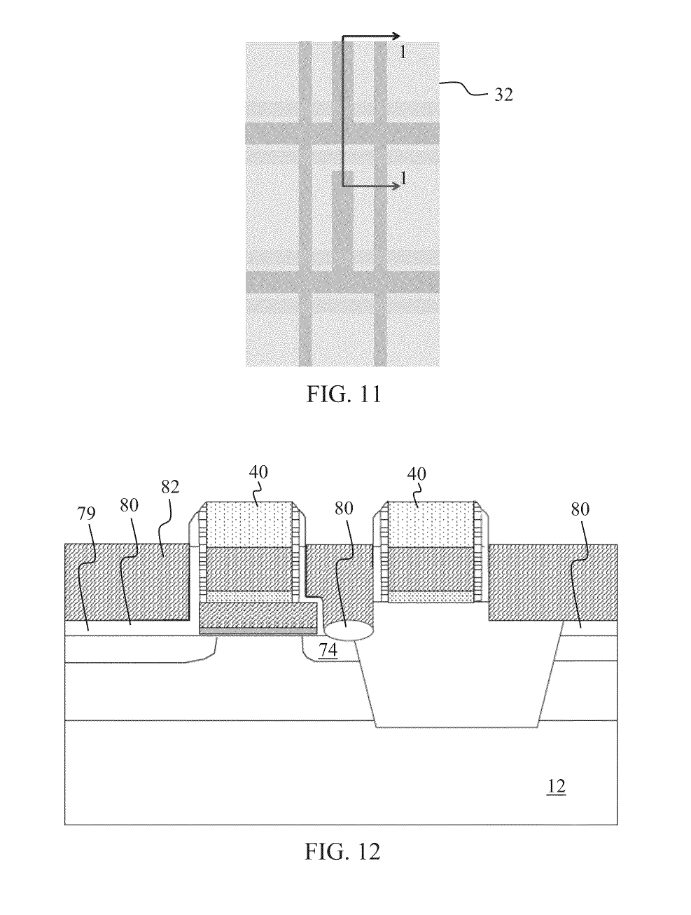

As shown in FIGS. 11-12, after forming tunnel oxide layer 79, a dielectric layer 80 is formed on the tunnel oxide layer 79 over the semiconductor substrate 12 and around the gate stacks 40. An exemplary dielectric layer 80 may be formed by thermal oxidation. An exemplary dielectric layer 80 has a thickness of from about 15 nm to about 40 nm. As shown, the dielectric layer 80 is formed with an oval shape over the source line region, i.e., the dielectric layer 80 has an increased thickness at its central portion at that location. This shape and increased thickness results from intrinsic behavior during thermal oxidation. Specifically, the oxide growth has a direct relationship to the amount of doping in the underlying material. As the source line region 74 is highly N-type doped, the oxide grows thicker over the source line region 74.

Dielectric layer 80 may be considered to be an input/output device gate oxide or “(I/O) oxide”. Dielectric layer 80 may be oxide grown in a wet or dry process. After forming dielectric layer 80, conductive gate material 82 is conformally deposited over the dielectric layer 80. Conductive gate material 82 is a material that may be processed to form an erase gate and select gates/word lines. An exemplary conductive gate material 82 is polysilicon. The deposition of the conductive gate material 82 may be performed by a well known process such as Low Pressure CVD (LPCVD). The mask used in FIG. 11 may be the same mask used in FIG. 5, with mask opening 32. Portions of the conductive gate material 82 may be planarized, such as by chemical-mechanical planarization, and recessed as shown in FIG. 12.

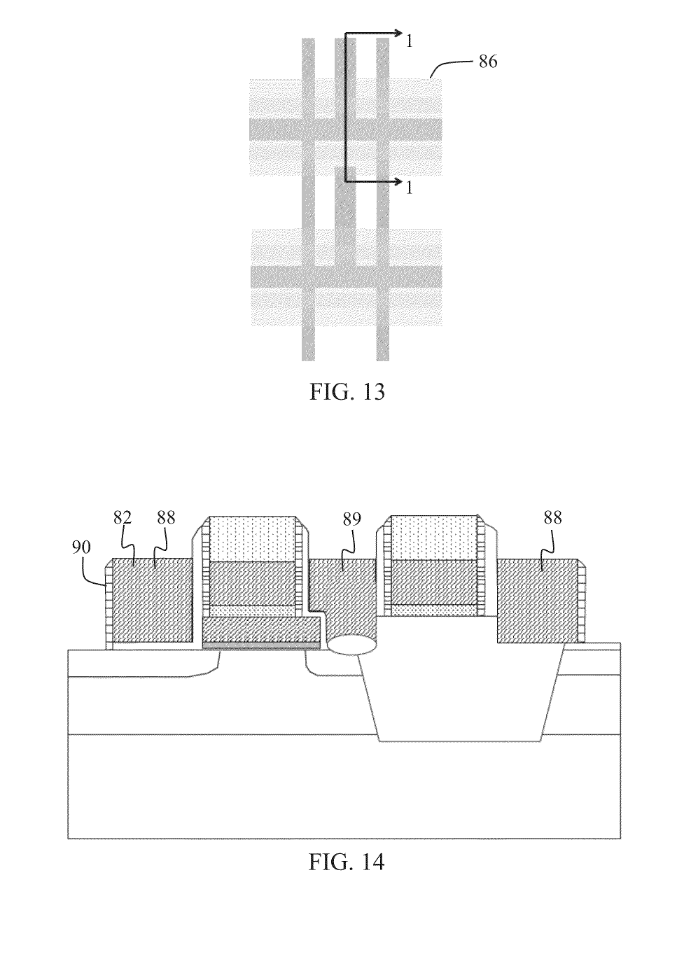

In FIGS. 13-14, a mask with mask opening 86 is used to pattern the conductive gate material 82 to form select gates 88 or word lines 88 and erase gate 89. Then spacers 90 may be formed around the select gates 88. For example, the spacers 90 may be nitride that is deposited and patterned.

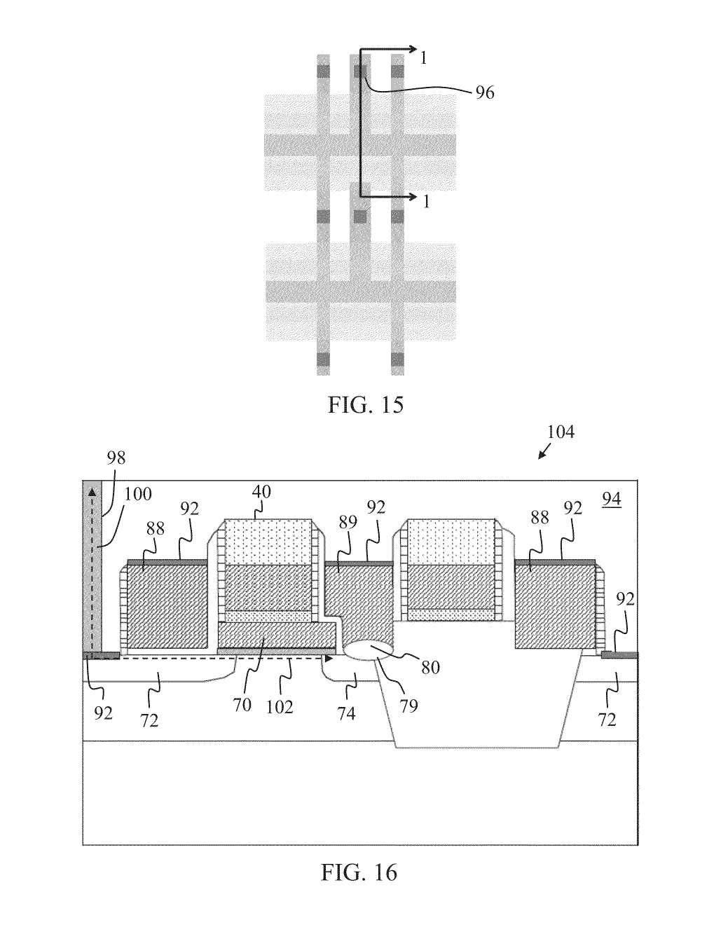

FIGS. 15-16 illustrate the formation of contacts 92 over shallow doped regions 72, select gates 88, and erase gate 89. As shown, an interlayer dielectric material 94 is then deposited over the integrated circuit 10. Using a mask with mask opening 96, a trench 98 is formed in the interlayer dielectric material 94 and is filled with a conductive material to form a conductive via 100 electrically connected to a selected contact 92 (on the left side of FIG. 16).

As a result of the process illustrated in FIGS. 1-16, an electrical conductive path 102, which may be considered to be a strap, is formed through conductive via 100, contact 92, shallow doped region 72 to source line region 74 for a memory cell. The conductive via 100 may be connected to a bit line or other conductive layer in an array as desired to provide for appropriate program, read, write and erase processes.

As may be seen in FIG. 16, the source line region 74 is completely covered, such as by tunnel oxide layer 79, dielectric layer 80 and erase gate 89. Further, the described embodiment provides electrical connection to the source line region 74 without etching the erase gate 89 or dielectric layer 80 or tunnel oxide layer 79. As shown, the electrical conductive path 102 is substantially horizontal from the source line region 74 to the contact 92 and is buried under the floating gate structure 70 and control gate stack 40 and under the select gate 88.

While not illustrated, conductive vias 100 may be formed to contact the select gates 88, erase gate 89, or control gate stack 40 as desired. The buried electrical connection to the source line region 74 provides for an enlarged process window for forming electrical connections to other features, as the source line region electrical connection is no longer located between the gate stacks 40.

In summary, a fabrication process is implemented to form an integrated circuit with improved nonvolatile memory devices. Electrical connection to source line regions are provided by buried horizontal electrical conductive paths that are located under floating gate/control gate stacks and select gates. The methods provided herein result in nonvolatile memory devices having improved performance.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A method for fabricating a memory cell, the method comprising:
doping a semiconductor substrate to define a conductive region;
forming a stacked structure over the semiconductor substrate, wherein the stacked structure includes a control gate overlying a floating gate, and wherein the stacked structure lies over the conductive region;
forming a source line region adjacent a first side of the stacked structure; and
forming a contact over the semiconductor substrate and adjacent a second side of the stacked structure to define an electrical current path from the source line region through the conductive region under the stacked structure to the contact.

2. The method of claim 1 further comprising depositing an insulating material over the source line region.

3. The method of claim 2 wherein depositing the insulating material over the source line region comprises forming an I/O oxide over the source line region.

4. The method of claim 2 further comprising forming an erase gate and a select gate over the semiconductor substrate, wherein the erase gate is located over the insulating material over the source line region, wherein the select gate is located between the second side of the stacked structure and the contact, and wherein the electrical current path passes under the select gate.

5. The method of claim 4 wherein depositing the insulating material over the source line region comprises depositing the insulating material over the semiconductor substrate adjacent the second side of the stacked structure, and wherein forming the erase gate and the select gate over the semiconductor substrate comprises:
depositing a gate material over the insulating material;
etching the gate material to define the erase gate overlying the source line region and a select gate adjacent the second side of the stacked structure.

6. The method of claim 1 further comprising:
depositing an interlayer dielectric over the stacked structure, contact and semiconductor substrate; and
forming a conductive via through the interlayer dielectric and in electrical connection to the contact.

7. The method of claim 1 further comprising:
forming an isolation region in the semiconductor substrate; and
forming a second control gate overlying the isolation region, wherein the source line region is defined between a second side of the second control gate and the stacked structure.

8. The method of claim 7 further comprising forming an erase gate and select gates over the semiconductor substrate, wherein the erase gate is located over the source line region, wherein a first select gate is located adjacent a first side of the second control gate, wherein a second select gate is located between the second side of the stacked structure and the contact, and wherein the electrical current path passes under the second select gate.

9. The method of claim 1 wherein doping the semiconductor substrate to define the conductive region comprises forming an N⁺ doped conductive region.

10. The method of claim 1 wherein forming the stacked structure over the semiconductor substrate comprises:
depositing a tunnel dielectric layer over the semiconductor substrate;
depositing a floating gate polysilicon layer over the tunnel dielectric layer;
depositing an inter-polysilicon dielectric layer over the floating gate polysilicon layer;
depositing a control gate polysilicon layer over the inter-polysilicon dielectric layer;
depositing a cap material over the control gate polysilicon layer;
etching the cap material, the control gate polysilicon layer, and the inter-polysilicon dielectric layer to form a control gate stack; and
etching the floating gate polysilicon layer and the tunnel dielectric layer to form a floating gate under the control gate stack.

11. The method of claim 10 further comprising:
forming an isolation region in the semiconductor substrate; and
forming a second control gate stack overlying the isolation region, wherein:
the source line region is defined between a second side of the second control gate and the stacked structure;
depositing the inter-polysilicon dielectric layer comprises depositing the inter-polysilicon dielectric layer over the isolation region; and
etching the cap material, the control gate polysilicon layer, and the inter-polysilicon dielectric layer comprises forming a first control gate stack and the second control gate stack.

12. A method for fabricating an integrated circuit, the method comprising:
forming a flash memory cell including a floating gate overlying a semiconductor substrate and a source line region adjacent a first side of the floating gate; and
forming a contact over the semiconductor substrate adjacent a second side of the floating gate and defining an electrical current path from the contact, under the floating gate, and to the source line region.

13. The method of claim 12 further comprising:
forming a dielectric layer over the source line region and an erase gate over the dielectric layer, wherein the source line region is buried by the dielectric layer and the erase gate; and
forming a conductive via in electrical connection to the contact, wherein the source line region remains buried by the dielectric layer and erase gate during electrical connection of the source line region to the conductive via.

14. The method of claim 12 further comprising doping the semiconductor substrate to define a conductive region, wherein the floating gate is formed over the conductive region.

15. The method of claim 14 further comprising forming a stacked structure over the semiconductor substrate, wherein the stacked structure includes a control gate overlying the floating gate.

16. An integrated circuit comprising:
a semiconductor substrate;
a source line region in or overlying the semiconductor substrate;
a contact in or overlying the semiconductor substrate and defining an electrical current path between the contact and the source line region; and
a gate overlying the semiconductor substrate and located between the source line region and the contact, wherein the electrical current path passes under the gate.

17. The integrated circuit of claim 16 wherein the gate includes a first control gate overlying a floating gate, and wherein the integrated circuit further comprises:
an erase gate overlying the source line region; and
a word line overlying the semiconductor substrate and located between the contact and the gate, wherein the electrical current path passes under the word line.

18. The integrated circuit of claim 17 further comprising:
a dielectric layer located between the source line region and the erase gate; and
a dielectric layer located between the semiconductor substrate and the word line.

19. The integrated circuit of claim 17 further comprising;
an isolation region located adjacent the source line region, wherein the source line region is located between the isolation region and the gate;
a second control gate overlying the isolation region, wherein the word line is located between the first control gate and the second control gate.

20. The integrated circuit of claim 19 further comprising:
an interlayer dielectric material overlying the semiconductor substrate, word line, first control gate, erase gate, and second control gate; and
a conductive via embedded in the interlayer dielectric material and in electrical connection with the contact.
